(19) United States
(12) Patent Application Publication
(10) Pub. No.: US 2012/0181503 A1
(43) Pub. Date: Jul. 19, 2012

(54) Method of Fabricating Silicon Quantum Dot Layer and Device Manufactured Using the Same

(76) Inventors: Czang-Ho Lee, Yongin-si (KR); Joon-Young Seo, Yongin-si (KR); Dong-Jin Kim, Yongin-si (KR)

(21) Appl. No.: 13/236,439

(22) Filed: Sep. 19, 2011

(30) Foreign Application Priority Data
Jan. 19, 2011 (KR) 10-2011-0005568

(51) Int. Cl. H01L 33/06; H01L 29/775; H01L 21/20; H01L 33/08; B82Y 40/00; B82Y 99/00

(52) U.S. Cl. 257/13; 438/488; 438/34; 257/24; 977/952; 977/774; 257/E21.09; 257/E33.003; 257/E29.245

(57) ABSTRACT

Disclosed are a method of fabricating a silicon quantum dot layer and a device manufactured using the same. A first capping layer is formed on a substrate, and a silicon-containing precursor layer is formed on the first capping layer. A second capping layer is formed on the silicon-containing precursor layer. The first capping layer, the silicon-containing precursor layer, and the second capping layer are irradiated to convert the silicon-containing precursor layer into a stack including a first poly-crystalline silicon layer, a silicon quantum dot layer on the first poly-crystalline silicon layer, and a second poly-crystalline silicon layer on the silicon quantum dot layer.

### CROSS-REFERENCE TO RELATED APPLICATION

This application relies for priority upon Korean Patent Application No. 10-2011-0005568 filed on Jan. 19, 2011, the contents of which are herein incorporated by reference in their entirety.

### BACKGROUND

1. Technical Field

The present disclosure relates to a method of fabricating a silicon quantum dot layer and a device manufactured using the same.

2. Description of Related Art

A photovoltaic conversion device converts light into electrical energy using a photovoltaic conversion layer. The photovoltaic conversion layer realizes a photovoltaic effect by absorbing energy of an external light and emitting free-electrons to produce a current.

Typically, the photovoltaic conversion layer includes amorphous silicon. The photovoltaic conversion device including the amorphous silicon are susceptible to a photo-degradation phenomenon and a reduction in efficiency.

### SUMMARY

According to an exemplary embodiment of the present disclosure, a method for fabricating a silicon quantum dot layer includes forming a first capping layer on a substrate, and forming a silicon-containing precursor layer on the first capping layer. A second capping layer is formed on the silicon-containing precursor layer. The first capping layer, the silicon-containing precursor layer, and the second capping layer are irradiated to convert the silicon-containing precursor layer into a stack comprising a first poly-crystalline silicon layer, a silicon quantum dot layer on the first poly-crystalline silicon layer, and a second poly-crystalline silicon layer on the silicon quantum dot layer.

According to an exemplary embodiment of the present disclosure, a photovoltaic conversion device includes a capping layer provided on a substrate, a first electrode layer provided on the capping layer, a photovoltaic conversion layer provided on the first electrode layer and comprising a silicon quantum dot layer, and a second electrode layer provided on the photovoltaic conversion layer. The photovoltaic conversion layer includes a first poly-crystalline silicon layer provided on the first electrode layer and doped with first conductive type impurities, wherein the silicon quantum dot layer is provided on the first poly-crystalline silicon layer, and a second poly-crystalline silicon layer provided on the silicon quantum dot layer and doped with second conductive type impurities.

According to an exemplary embodiment of the present disclosure, a display device includes a plurality of pixels, and each pixel includes a capping layer provided on a substrate, a first electrode layer provided on the capping layer, a light emitting layer provided on the first electrode layer and comprising a silicon quantum dot layer, and a second electrode layer provided on the light emitting layer.

According to an exemplary embodiment of the present disclosure, a thin film transistor substrate includes a capping layer provided on a substrate, a source electrode, a drain electrode, a silicon quantum dot layer, a gate insulating layer, and a gate electrode.

The source electrode includes a poly-crystalline silicon layer provided on the capping layer and doped with first conductive type impurities. The drain electrode includes a poly-crystalline silicon layer doped with second conductive type impurities. The silicon quantum dot layer forms a channel interposed between the source electrode and the drain electrode. The gate insulating layer covers the channel, and the gate electrode is provided on the gate insulating layer.

### BRIEF DESCRIPTION OF THE DRAWINGS

Exemplary embodiments of the present disclosure will become readily apparent by reference to the following detailed description when considered in conjunction with the accompanying drawings wherein:

FIGS. 1A and 1B are sectional views sequentially showing a method of fabricating a silicon quantum dot layer according to a first embodiment of the present disclosure;

FIGS. 2A and 2B are photographs showing a bright-field image and a dark field image of TEM of multi-layers formed through the method according to the first embodiment of the present disclosure;

FIG. 3 is a selection of photographs of a TEM image of the silicon quantum dot layer of the multi-layer formed through the method according to the first embodiment of the present disclosure, and particularly, illustrates a bright-field image and an EDS result in a predetermined region of the bright-field image;

FIG. 4 is an XRD (X-ray diffraction) graph of the multi-layer formed through the method according to the first embodiment of the present disclosure;

FIG. 5 is a sectional view showing a photovoltaic conversion device according to a second embodiment of the present disclosure;

FIGS. 6A to 6D are sectional views sequentially showing a method of manufacturing a photovoltaic conversion device according to a third embodiment of the present disclosure;

FIG. 7 is a sectional view showing a photovoltaic conversion device according to a fourth embodiment of the present disclosure;

FIG. 8 is a sectional view showing a photovoltaic conversion device according to a fifth embodiment of the present disclosure;

FIG. 9 is a sectional view showing a display device according to a sixth embodiment of the present disclosure; and

FIG. 10 is a sectional view showing a thin film transistor substrate according to a seventh embodiment of the present disclosure.

### DESCRIPTION OF EXEMPLARY EMBODIMENTS

The present disclosure can be modified in various forms and for various applications. Exemplary embodiments are provided to impart the technical spirit of the present disclosure to the one of ordinary skill in the art. Therefore, the scope of the present disclosure is not be limited to exemplary embodiments described herein.

In the drawings, the same reference numerals designate the same components. The dimensions of layers and regions in the drawings and described in exemplary embodiments may be simplified or exaggerated for precise explanation or emphasis. Number terms such as ‘first’ and ‘second’ are used for the purpose of explanation about various components, and the components are not limited by the terms ‘first’ and ‘second’. The terms ‘first’ and ‘second’ are only used to distinguish one component from another component. For example, a first component may be named as a second component without deviating from the scope of the present disclosure. Similarly, the second component may be named as the first component. The expression of a singular number in the specification includes the meaning of a plural number unless the context indicates otherwise.

In the following description, the term ‘include’ or ‘have’ may represent the existence of a feature, a number, a step, an operation, a component, a part or the combination thereof described in the specification, and may not exclude the existence or addition of another feature, another number, another step, another operation, another component, another part or the combination thereof. In addition, when a layer, a film, a region, or a plate is mentioned as to be formed on another layer, another film, another region, or another plate, the layer, the film, the region, or the plate may be directly formed on another layer, another film, another region, or another plate, or a third layer, a third film, a third region, or a third plate may be interposed between the layer, the film, the region, or the plate and another layer, another film, another region, or another plate. When a layer, a film, a region, or a plate is mentioned as to be formed below another layer, another film, another region, or another plate, the layer, the film, the region, or the plate may be directly formed under another layer, another film, another region, or another plate, or a third layer, a third film, a third region, or a third plate may be interposed between the layer, the film, the region, or the plate and another layer, another film, another region, or another plate. For the purpose of explanation, a portion of a display panel on which an image is displayed will be referred to as ‘an upper portion’, ‘a front portion’, or ‘a front direction’ and a portion or a direction opposite to the ‘upper portion’, ‘front portion’, or ‘front direction’ will be referred to as ‘a lower portion’, ‘a rear portion’, or ‘a rear direction’.

Exemplary embodiments of the present disclosure include a method of fabricating a silicon quantum dot layer, a device including silicon quantum dots, and a method of manufacturing the device. A quantum dot is a semiconductor whose excitons are confined in the three spatial dimensions. The quantum dot exhibits electronic characteristics related to a size and shape of an underlying poly-crystalline silicon device.

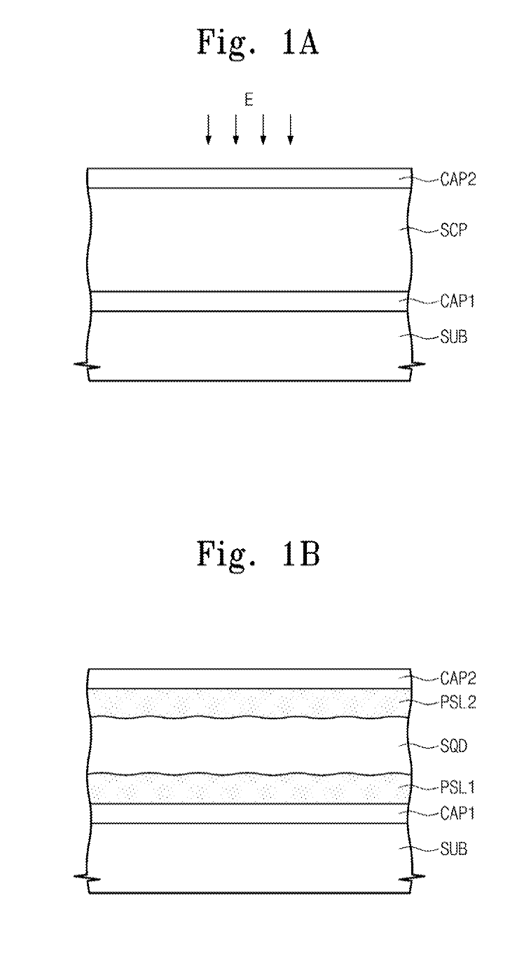

FIGS. 1A and 1B are sectional views sequentially showing processes of fabricating a silicon quantum dot layer SQD according to a first exemplary embodiment of the present disclosure.

Referring to FIGS. 1A and 1B, in order to fabricate the silicon quantum dot layer SQD, after sequentially forming a first capping layer CAP1, a silicon-containing precursor layer SCP, and a second capping layer CAP2 on a substrate SUB, the first capping layer CAP1, the silicon-containing precursor layer SCP, and the second capping layer CAP2 are subject to a post treatment.

The first capping layer CAP1 is formed on the substrate SUB. The substrate SUB may include an insulating material such as glass, quartz, plastic, or silicon. The first capping layer CAP1 may include various inorganic materials such as at least one of silicon oxide (SiO₂), silicon nitride (SiN), or silicon oxynitride (SiON).

The silicon-containing precursor layer SCP includes silicon-containing precursors. The silicon-containing precursors may generate silicon quantum dots through a specific process. The silicon-containing precursor includes a silicon-rich material. In one embodiment, the silicon-rich material comprises at least one of amorphous silicon (a-Si), silicon-rich silicon nitride (SiN), silicon-rich silicon dioxide (SiO), or silicon-rich silicon carbide (SiC). The second capping layer CAP2 is formed on the silicon-containing precursor layer SCP. The second capping layer CPA2 may include an inorganic material, such as at least one of SiO₂, SiN, or SiON. The first capping layer CAP1 and the second capping layer CAP2 may be formed of the same material(s) as one another or a different material(s) different from one another.

The first capping layer CAP1 and the second capping layer CAP2 transfer heat to the silicon-containing precursor layer SCP when the post treatment is performed on the silicon-containing precursor layer SCP. The first and second capping layers CAP1 and CAP2 convert photons emitted from a light source, e.g., photo-energy of a laser beam or a flashlight, into thermal energy and absorb and retain the thermal energy in the post treatment. Furthermore, the first and second capping layers CAP1 and CAP2 transfer the thermal energy to the silicon-containing precursor layer SCP. In addition, the first and second capping layers CAP1 and CAP2 substantially prevent external impurities from being diffused into the silicon-containing precursor layer SCP. In particular, the first capping layer CAP1 substantially prevents the external impurities existing on the substrate SUB from infiltrating into the silicon-containing precursor layers SCP.

The post treatment is performed by supplying high-power photo-energy E to the first capping layer CAP1, the silicon-containing precursor layer SCP, and the second capping layer CAP2. Through the post treatment, the silicon-containing precursor layer SCP is converted into a first poly-crystalline silicone layer PSL1, a silicon quantum dot layer SQD, and a second poly-crystalline silicon layer PSL2 that are sequentially stacked on each other. The photo-energy E is supplied to the silicon-containing precursor layer SCP by irradiating a continuous wave laser beam into the silicon-containing precursor layer SCP or by using a flashlight.

The high-power photo-energy E is absorbed into silicon-containing precursors of the silicon-containing precursor layer SCP and converted into thermal energy, and silicon quantum dots are grown from the silicon-containing precursors are grown by the thermal energy. The first and second capping layers CAP1 and CAP2 are provided at the top and bottom of the silicon-containing precursor layer SCP to uniformly transfer the thermal energy to an entire portion of the silicon-containing precursor layer SCP, remove columnar crystal or substantially prevent columnar crystal from being grown, and prevent thermal energy of the silicon-containing precursors from being discharged to an outside. Accordingly, the silicon-containing precursor layer SCP is converted into the silicon quantum dot layer SQD formed having uniformly distributing silicon quantum dots in an amorphous silicon layer. In this case, portions of the silicon-containing precursor layer SCP adjacent to the first capping layer CAP1 and the second capping layer CAP2 are crystallized by receiving the thermal energy, which is absorbed and charged in the first and second capping layers CAP1 and CAP2 while being converted from the photo-energy E, as well as thermal energy, which is absorbed and charged in the silicon-containing precursor layer SCP. Therefore, a predetermined region of the silicon-containing precursor layer SCP adjacent to the first capping layer CAP1 is converted into a first poly-crystalline silicone layer PSL1, and a predetermined region of the silicon-containing precursor layer SCP in the contact with the second capping layer CAP2 is converted into a second poly-crystalline silicone layer PSL2. In this case, the characteristics of the first poly-crystalline silicon layer PSL1, the second poly-crystalline silicon layer PSL2, and the silicon quantum dot layer SQD can be adjusted according to process conditions of the post treatment, the thicknesses of the first capping layer CAP1 and the second capping layer CAP2, and the thickness of the silicon-containing precursor layer SCP.

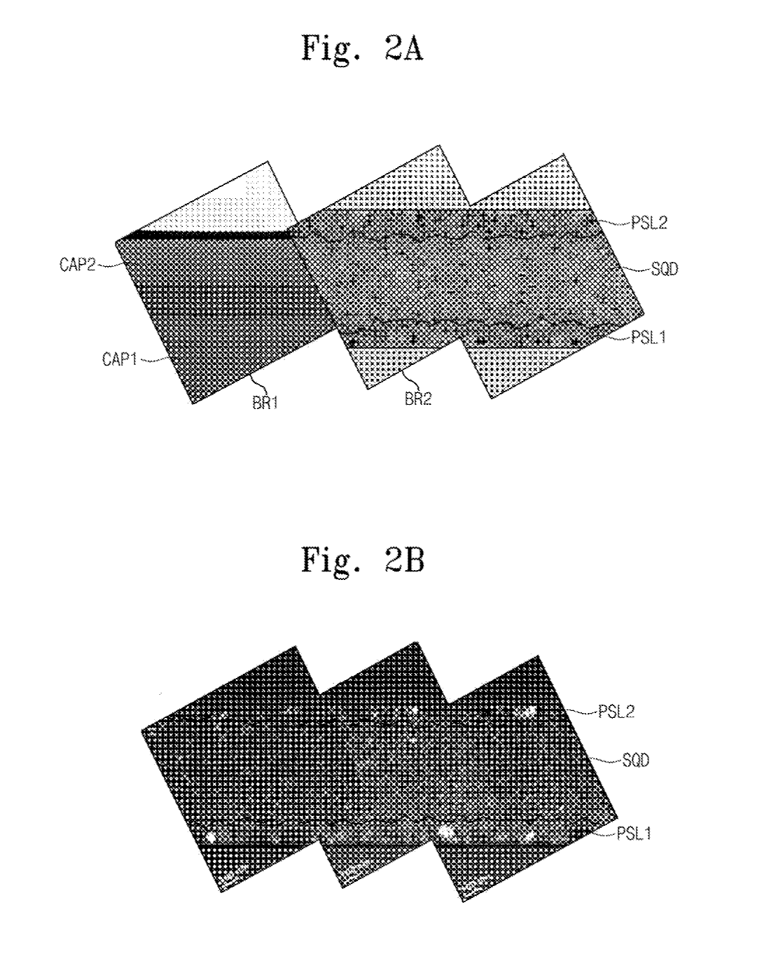

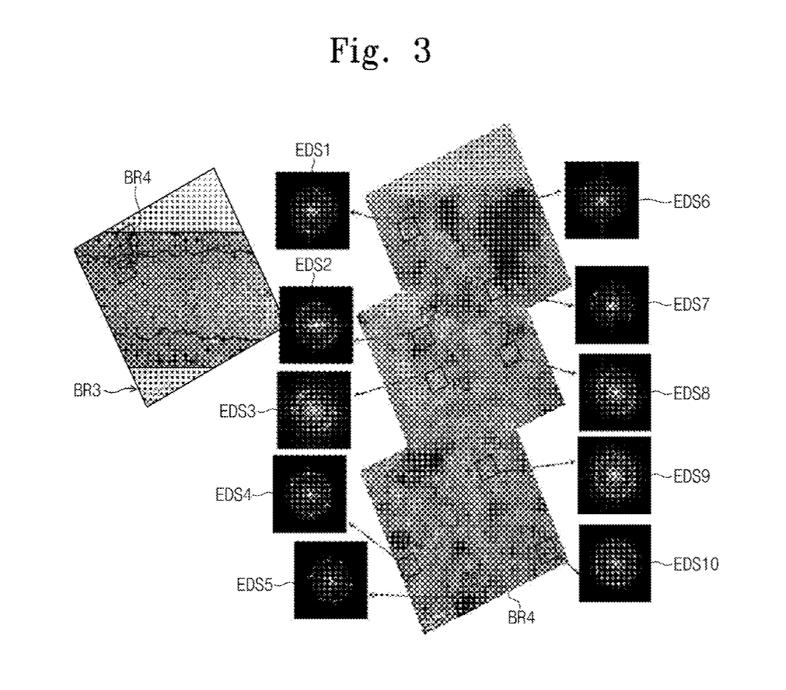

FIGS. 2A and 2B are photographs showing TEM (Transmission Electron Microscope) images of layered structures formed through the method according to the first embodiment of the present disclosure. More particularly, FIGS. 2A and 2B are photographs showing a bright-field image and a dark-field image of the layered structures, respectively. FIG. 3 is a selection of TEM images of different silicon quantum dot layers SQD formed through the method according to the first embodiment of the present disclosure. More particularly, FIG. 3 shows bright-field images and EDS (Energy Dispersive Spectroscopy) resulting in predetermined regions of the bright-field images.

Reference characters BR2 of FIG. 2A and BR3 of FIG. 3 show an enlarged photograph of a predetermined region in the silicon quantum dot layer SQD represented as reference character BR1 in FIG. 2A. FIG. 2B shows a dark-field image in the predetermined region of the silicon quantum dot layer SQD represented as reference character BR1 in FIG. 2A. Reference character BR4 of FIG. 3 shows an enlarged image of a polygonal region indicated by the reference character BR3. As shown in FIG. 3, first to tenth points P1 to P10 are randomly determined in a region of reference character BR4, and EDS results at the first to tenth points P1 to P10 are marked as reference characters EDS1 to EDS10.

As shown in FIGS. 2A, 2B, and 3, in order to form the silicon quantum dot layer SQD, the first capping layer CAP1 includes a SiO₂ layer having a thickness of about 3500 □, and the second capping layer CPA2 includes a SiO₂ layer having a thickness of about 1 μm. In addition, the silicon-containing precursor layer SCP includes amorphous silicon, and has a thickness of about 7000 □. The first capping layer CAP1, the second capping layer CAP2, and the silicon-containing precursor layer SCP are subject to the post treatment by a continuous wave laser.

FIGS. 2A, 2B, and 3 show poly-crystalline silicon layers observed at regions adjacent to the first and second capping layers CAP1 and CAP2. Accordingly, the first and second poly-crystalline silicon layers PSL1 and PSL2 can be recognized.

Silicon quantum dots formed between the first and second poly-crystalline silicon layers PSL1 and PSL2 are shown in the EDS images of FIG. 3. Referring to FIG. 3, EDS images at first, second, sixth, and seventh points P1, P2, P6, and P7 show poly-crystalline silicon layers. EDS images of fourth, fifth, eighth, and tenth points P4, P5, P8, and P10 show silicon quantum dots. In addition, EDS images at third and ninth points P3 and P9 show that amorphous silicon layers are maintained.

Therefore, FIGS. 2A, 2B, and 3 show that the first poly-crystalline silicon layer PSL1 is formed directly on the first capping layer CAP1, the silicon quantum dot layer SQD is formed directly on the first poly-crystalline silicon layer PSL1, and the second poly-crystalline silicon layer PSL2 is formed directly on the silicon quantum dot layer SQD. Although not shown in FIGS. 2A, 2B, and 3, when predetermined regions of the silicon quantum dot layer SQD are examined, the silicon quantum dots uniformly distributed in the amorphous silicon can be recognized.

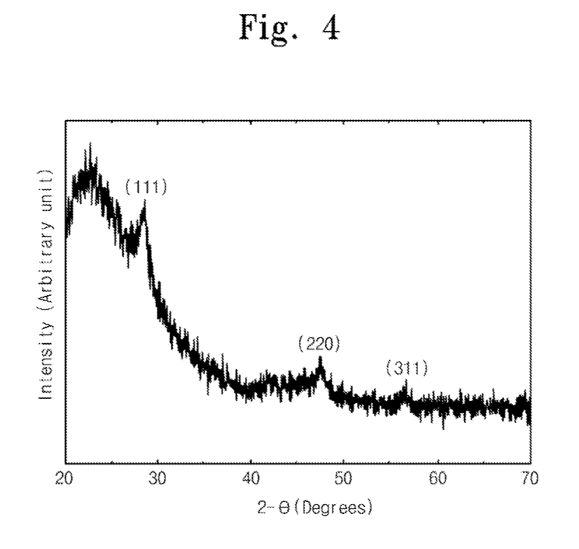

FIG. 4 is an XRD (X-ray diffraction) graph of the silicon quantum dot layer SQD formed according to the first embodiment of the present disclosure. Referring to FIG. 4, grains of silicon quantum dots are randomly grown as <111>, <220>, and <311>.

The silicon quantum dot layer SQD fabricated through the exemplary method shown in FIGS. 2A, 2B, and 3 is applicable to various devices by using the physical characteristics of the silicon quantum dots. Each silicon quantum dot has a quantum confinement effect. The quantum confinement effect refers to a phenomenon in which the energy band gap of a material is increased if the size of a material is reduced to a Bohr exciton radius or less. Accordingly, energy corresponding to the band gap may be discharged or absorbed according to the types of quantum dots. Therefore, the silicon quantum dots are applicable to, for example, a photovoltaic conversion device, a display device, or the semiconductor layer of a thin film transistor.

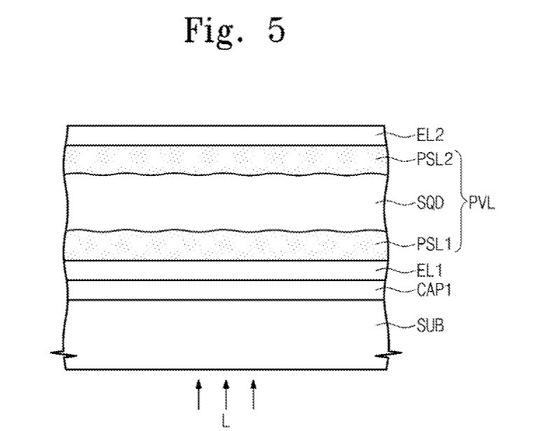

FIG. 5 is a sectional view showing a photovoltaic conversion device including a silicon quantum dot layer according to a second exemplary embodiment of the present disclosure.

Referring to FIG. 5, the photovoltaic conversion device according to the second exemplary embodiment of the present disclosure includes the substrate SUB, the first capping layer CAP1, a first electrode layer EL1, a photovoltaic conversion layer PVL, and a second electrode layer EL2. The first capping layer CAP1 and the first electrode layer EL1 are sequentially formed on the substrate SUB, and the photovoltaic conversion layer PVL is interposed between the first electrode layer EL1 and the second electrode layer EL2.

The first capping layer CAP1 may include at least one of SiO₂, SiN, or SiON. The first capping layer CAP1 substantially prevents impurities existing on the substrate SUB from infiltrating into the photovoltaic conversion layer PVL. In addition, the first capping layer CAP1 includes an anti-reflective layer to supply external light to the photovoltaic conversion layer PVL. The anti-reflective layer reduces reflection of light L to an exterior of the photovoltaic conversion device and increases the absorption of the light by the photovoltaic conversion layer PVL.

The first electrode layer EL1 may include a transparent conductive layer such as a TCO (transparent conductive oxide) including at least one of tin oxide (SnO₂), indium tin oxide (ITO), zinc oxide (ZnO), indium zinc oxide (IZO), or indium tin zinc oxide (ITZO). The first electrode layer EL1 may be subject to a texturing process. Through the texturing process, the surface area of the first electrode layer EL1 for collection light is expanded. The second electrode layer EL2 may include at least one of aluminum (Al), silver (Ag), gold (Au), copper (Cu), platinum (Pt), or chrome (Cr).

The photovoltaic conversion layer PVL is provided on the first electrode layer EL1. The photovoltaic conversion layer PVL includes the first poly-crystalline silicon layer PSL1, the silicon quantum dot layer SQD, and the second poly-crystalline silicon layer PSL2 that are sequentially stacked on the first electrode layer EL1.

The first poly-crystalline silicon layer PSL1 is doped with first conductive type impurities creating an excess of a first type of electron charge carrier, and the second poly-crystalline silicon layer PSL2 is doped with second conductive type impurities creating an excess of a second type of electron charge carrier having a polarity opposite to a polarity of the first type electron charge carrier. For example, according to one exemplary embodiment of the present disclosure, the first poly-crystalline silicon layer PSL1 may include a P type conductive layer formed by doping boron (B) into a poly-crystalline silicon layer and having an excess of holes as compared to electrons, and the second poly-crystalline silicon layer PSL2 may include an N type conductive layer formed by doping phosphorous (P) into a poly-crystalline silicon layer and having an excess of electrons as compared to holes. According to another exemplary embodiment of the present disclosure, the first poly-crystalline silicon layer PSL1 may include an N type conductive layer formed by doping phosphorous (P) into a poly-crystalline silicon layer and having an excess of electrons, and the second poly-crystalline silicon layer PSL2 may include a P type conductive layer formed by doping boron (B) into a poly-crystalline silicon layer and having an excess of holes.

The silicon quantum dot layer SQD includes silicon quantum dots formed in the amorphous silicon layer. The silicon quantum dots are uniformly distributed in the amorphous silicon layer. In this case, since the silicon quantum dots may be uniformly distributed in the silicon quantum dot layer SQD, and the energy band gap of the silicon quantum dots may vary according to the size of particles. Therefore, the silicon quantum dots can absorb photons having various energies. In addition, when the silicon quantum dots absorb photons having energy two times greater than energy band gap, at least two electrons in the silicon quantum dot are excited. This phenomenon may be referred to as multiple exciton generation. Accordingly, the photovoltaic interaction occurs while thermal energy is reduced.

The photovoltaic conversion device having the exemplary structure of FIG. 5 operates according to the following mechanism. If an external light L is supplied to the silicon quantum dot layer SQD, the silicon quantum dots of the silicon quantum dot layer SQD absorb photons of the external light L. If the silicon quantum dots absorb the photons, the outer most electrons of the silicon quantum dots are excited, so that electron-hole pairs are formed. The electron-hole pairs generate an electromotive force.

In the photovoltaic conversion device according to the second exemplary embodiment of the present disclosure, the photovoltaic conversion layer PVL including the silicon quantum dot layer SQD is used in order to reduce or prevent the photo-degradation phenomenon occurring in an a-Si single junction photovoltaic conversion device or an a-Si/μc-Si tandem junction photovoltaic conversion device.

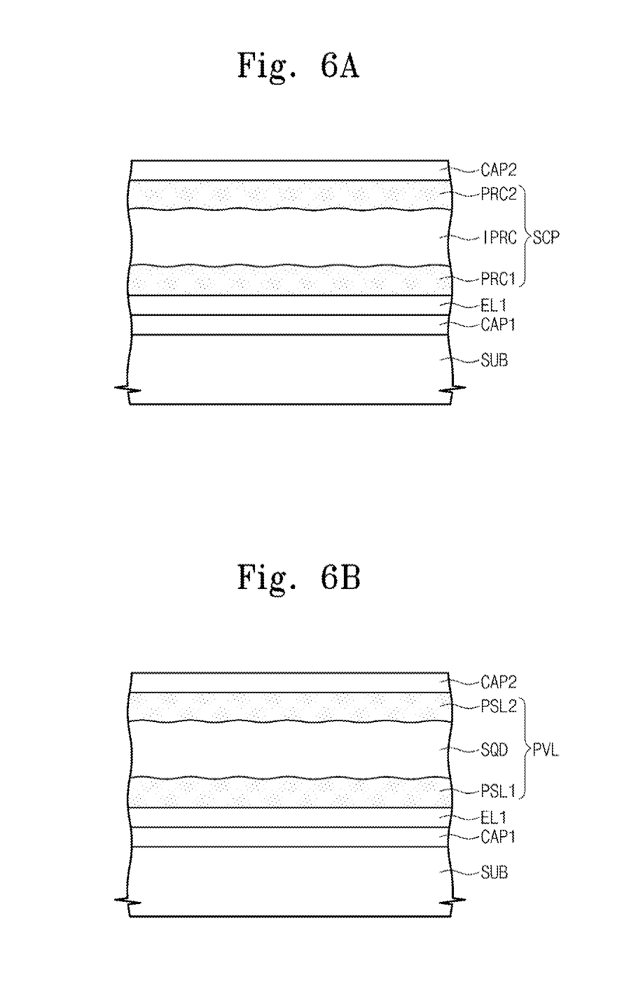

FIGS. 6A to 6D are sectional views sequentially showing a method of manufacturing a photovoltaic conversion device according to a third exemplary embodiment of the present disclosure. Structures and components of the third exemplary embodiment found in the second exemplary embodiment will not be further described. In addition, for the purpose of explanation, the same reference numbers are used in connection with the same components of the second exemplary embodiment.

Referring to FIG. 6A, the first capping layer CAP1, the first electrode layer EL1, the silicon-containing precursor layer SCP, and the second capping layer CAP2 are sequentially formed on the substrate SUB.

The first capping layer CAP1 may be formed by depositing at least one of SiO₂, SiN, or SiON on the substrate SUB.

The first electrode layer ELI may be formed by depositing TCO such as at least one of SnO₂, ITO, ZnO, IZO, or ITZO on the first capping layer CAP1.

The silicon-containing precursor layer SCP may include at least one of amorphous silicon, silicon-rich silicon nitride (SiNx), silicon-rich silicon dioxide (SiO), or silicon-rich silicon carbide (SiC).

The silicon-containing precursor layer SCP includes a first precursor layer PRC1, an intermediate precursor layer IPRC, and a second precursor layer PRC2. The first precursor layer PRC1 is formed by depositing the silicon-containing precursor on the first electrode layer ELI and doping the first precursor layer PRC1 with the first conductive type impurities. The intermediate precursor layer IPRC is formed by depositing silicon-containing precursor, which is not doped with impurities, on the first precursor layer PRC1. The second precursor layer PRC2 is formed by depositing the silicon-containing precursor on the intermediate precursor layer IPRC and doping the second precursor layer PRC2 with the second conductive type impurities having an electron charge carrier with a polarity opposite to that of an electron charge carrier of the first conductive type impurities. According to one embodiment of the present disclosure, the first conductive type impurities may include N type impurities such as P, and the second conductive type impurities may include P type impurities such as B. In contrast, according to another exemplary embodiment of the present disclosure, the first conductive type impurities may include P type impurities such as B, and the second conductive type impurities may include N type impurities such as P.

The second capping layer CAP2 may be formed by depositing at least one of SiO₂, SiN, or SiON on the second precursor layer PRC2.

Referring to FIG. 6B, after the substrate SUB including the first capping layer CAP1, the first electrode layer ELI, the silicon-containing precursor layer SCP, and the second capping layer CAP2 has been subject to the post treatment, the photovoltaic conversion layer PVL is generated.

The post treatment is performed by supplying high-power photo-energy to the first capping layer CAP1, the first electrode layer EL1, the silicon-containing precursor layer SCP, and the second capping layer CAP2 of FIG. 6A. The photo-energy may be supplied to the silicon-containing precursor layer SCP by a continuous wave laser beam or the light of a flashlight.

Through the post treatment, the first precursor layer PRC1, the intermediate precursor layer IPRC, and the second precursor layer PRC2 are converted into the first poly-crystalline silicon layer PSL1, the silicon quantum dot layer SQD, and the second poly-crystalline silicon layer PSL2, respectively. In this case, the first poly-silicon layer PSL1 includes poly-crystalline silicon doped with the first conductive type impurities, and the second poly-crystalline silicon layer PSL2 includes poly-crystalline silicon doped with the second conductive type impurities.

Referring to FIG. 6C, the second capping layer CAP2 is removed, for example by an etching process. After the second capping layer CAP2 has been removed, the first poly-crystalline silicon layer PSL1, the silicon quantum dot layer SQD, and the second poly-crystalline silicon layer PSL2 are hydrotreated.

Referring to FIG. 6D, the second electrode layer EL2 is deposited on the second poly-crystalline silicon layer PSL2. The second electrode layer EL2 may be formed by deposing a metallic material including at least one of Al, Ag, Au, Cu, Pt, or Cr. Although not shown, a reflective layer may be interposed between the second poly-crystalline silicon layer PSL2 and the second electrode layer EL2 to return back-reflected light into the photovoltaic conversion device so that the quantity of light incident onto the photovoltaic conversion layer PVL can be increased.

According to the method of manufacturing the photovoltaic conversion device according to the third exemplary embodiment of the present disclosure, the first and second poly-crystalline silicon layers PLS1 and PLS2 and the silicon quantum dot layer SQD interposed between the first and second poly-crystalline silicon layers PLS1 and PLS2 may be formed through a single step by using high-power photons. Therefore, the silicon quantum dot layer SQD can be formed at the low temperature. Accordingly, the photovoltaic conversion device can be manufactured using a substrate SUB having a low temperature tolerance.

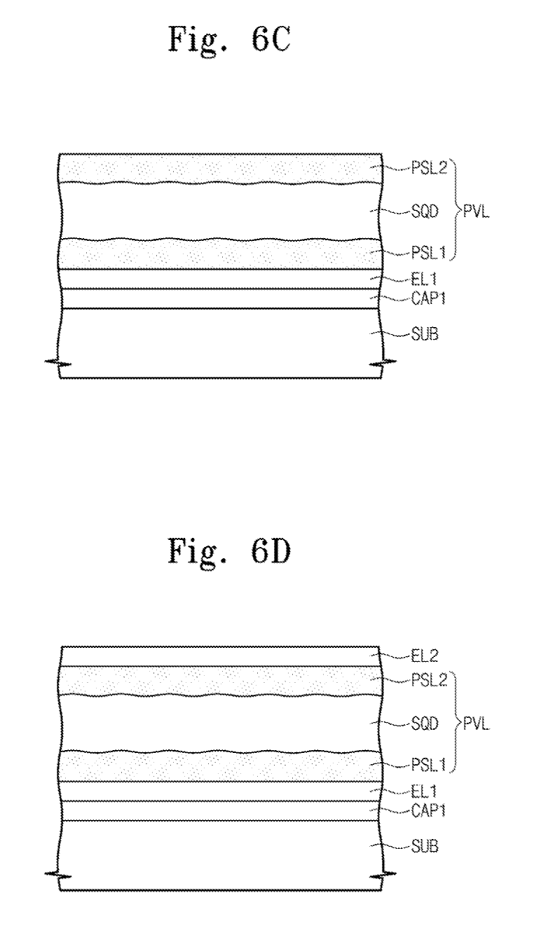

FIG. 7 is a sectional view showing a double-junction photovoltaic conversion device including a silicon quantum dot layer according to a fourth exemplary embodiment of the present disclosure. Hereinafter, the fourth exemplary embodiment is described in terms of the second exemplary embodiment. Structures and components of the fourth exemplary embodiment found in the second exemplary embodiment will not be further described. In addition, for the purpose of explanation, the same reference numbers are used in connection with the same components of the second exemplary embodiment.

Referring to FIG. 7, the photovoltaic conversion device according to the fourth exemplary embodiment of the present disclosure includes the substrate SUB, the first capping layer CAP1, the first electrode layer EL1, a first photovoltaic conversion layer PVL1, a second photovoltaic conversion layer PVL2, and the second electrode layer EL2. The first capping layer CAP1 and the first electrode layer EL1 are sequentially provided on the substrate SUB. The first and second photovoltaic conversion layers PVL1 and PVL2 are interposed between the first and second electrode layers EL1 and EL2.

The first photovoltaic conversion layer PVL1 is stacked on the first electrode layer EL1, and has a structure substantially identical to that of the photovoltaic conversion layer PVL according to the second exemplary embodiment.

The second photovoltaic conversion layer PVL2 is interposed between the first photovoltaic conversion layer PVL1 and the second electrode layer EL2. The second photovoltaic conversion layer PVL2 includes a first micro-crystalline (μ-crystalline or μc) silicon layer MCS1, an intrinsic crystalline silicon layer IMCS, and a second micro-crystalline silicon layer MCS2 stacked on the second poly-crystalline silicon layer PSL2 of the first photovoltaic conversion layer PVL1. The first micro-crystalline silicon layer MCS1 is formed directly on the second poly-crystalline silicon layer PSL2. The first micro-crystalline silicon layer MCS1 is doped with impurities (e.g., first conductive type impurities) creating an excess of a first type of electron charge carrier having a polarity opposite to a polarity of a second type of electron charge carrier of the second poly-crystalline silicon layer PSL2. The second micro-crystalline silicon layer MCS2 may be doped with the second conductive type impurities.

Similarly to the first photovoltaic conversion layer PVL1, the second photovoltaic conversion layer PVL2 receives and absorbs photo-energy of an external light so that electron-hole pairs are generated. If the first micro-crystalline silicon layer MCS1 is biased to a negative polarity, and the second micro-crystalline silicon layer MCS2 is biased to a positive polarity in the state that the electron-hole pairs are generated, the electrons move toward the second micro-crystalline silicon layer MCS2 to generate the electromotive force.

The photovoltaic conversion device according to the fourth exemplary embodiment of the present disclosure may be formed by forming the first capping layer CAP1, the first electrode layer EL1, and the first photovoltaic conversion layer PVL1 on the substrate SUB, and sequentially stacking the first micro-crystalline silicon layer MCS1, the intrinsic micro-crystalline silicon layer IMCS, and the second micro-crystalline silicon layer MCS2 on the first photovoltaic conversion layer PVL1. The first micro-crystalline silicon layer MCS1 may be formed by depositing micro-crystalline silicon on the second poly-crystalline silicon layer PSL2. The first micro-crystalline silicon layer MCS1 may be doped with the first conductive type impurities. Micro-crystalline silicon may be deposited on the first micro-crystalline silicon layer MCS1, and the second conductive type impurities are doped into an upper portion of the micro-crystalline silicon, thereby forming the intrinsic micro-crystalline silicon layer IMCS and the second micro-crystalline silicon layer MCS2. The second electrode layer EL2 may be formed on the second poly-crystalline silicon layer through a deposition scheme.

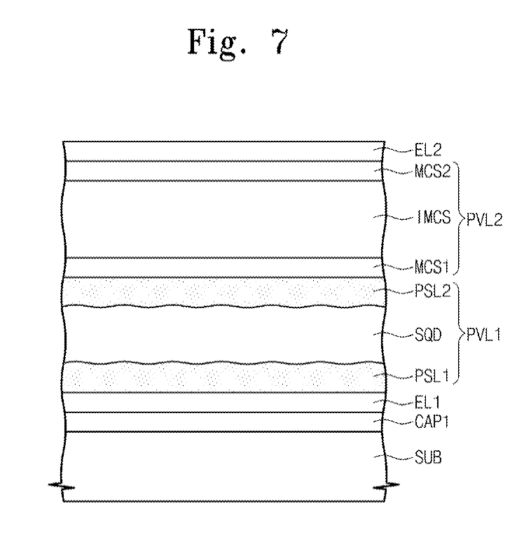

FIG. 8 is a sectional view showing a photovoltaic conversion device including a plurality of photovoltaic units according to a fifth exemplary embodiment of the present disclosure. Hereinafter, the fifth exemplary embodiment will be described in terms of the second exemplary embodiment. Structures and components of the fifth exemplary embodiment that are found in the second exemplary embodiment will not be further described. In addition, for the purpose of explanation, the same reference numbers are used in connection with the same components of the second exemplary embodiment.

Referring to FIG. 8, the photovoltaic conversion device includes the substrate SUB having a plurality of cell regions. A plurality of photovoltaic conversion cells CL corresponding to the cell regions are provided on the substrate SUB. The photovoltaic conversion cells CL may be connected to each other in series.

The photovoltaic conversion cells CL can have a structure similar to that of the photovoltaic conversion device according to the second exemplary embodiment shown in FIG. 5. In FIG. 8 adjacent photovoltaic conversion cells CL may be connected to each other in series.

In detail, each photovoltaic conversion cell CL includes the first electrode layer EL1, the photovoltaic conversion layer PVL, and the second electrode layer EL2. The first electrode layer EL1 is divided in the unit of a cell region by a first separation groove Va, and the photovoltaic conversion layer PVL is divided in the unit of a cell region by a third separation groove Vc.

The first separation groove Va and the third separation groove Vc may be formed through a laser process. In addition, the photovoltaic conversion layer PVL is patterned to form a second separation groove Vb to expose the first electrode layer EL1 of an adjacent photovoltaic conversion cell CL. The second separation groove Vb may be formed through the laser process. The second electrode layer EL2 is electrically connected to the first electrode layer EL1 of the adjacent photovoltaic conversion cell CL through the second separation groove Vb. Thus, the photovoltaic conversion cells CL can be connected to each other in series.

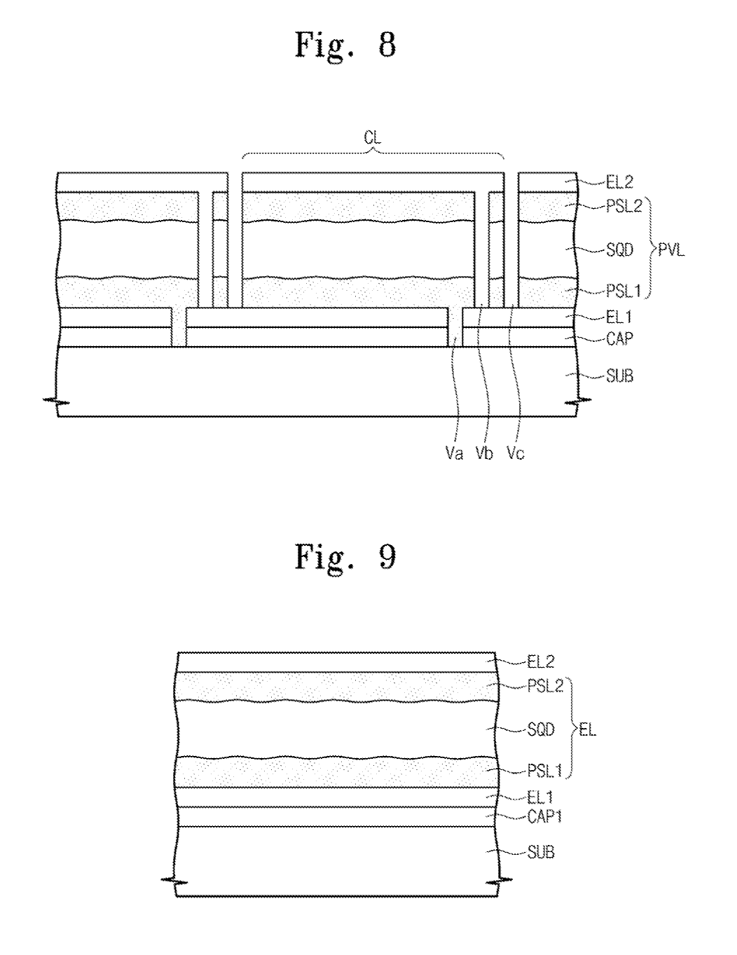

FIG. 9 is a sectional view showing a display device including the silicon quantum dot layer SQD according to a sixth exemplary embodiment of the present disclosure. The display device according to the sixth exemplary embodiment has the structure similar to that of the photovoltaic conversion device according to the second exemplary embodiment. The sixth embodiment will be described in the context of the second exemplary embodiment. Structures and components of the sixth exemplary embodiment found in of the second exemplary embodiment will not be further described. In addition, for the purpose of explanation, the same reference numbers are used in connection with the same components of the second exemplary embodiment.

The display device includes the substrate SUB having a plurality of pixel regions. The substrate SUB is provided on a plurality of light emitting devices corresponding to the pixel regions. Since the light emitting devices have the same structure, FIG. 9 shows an exemplary light emitting device.

Referring to FIG. 9, the display device according to the sixth exemplary embodiment includes the light emitting device including the substrate SUB, the capping layer CAP1, the first electrode layer EL1, a light emitting layer EL, and the second electrode layer EL2. The capping layer CAP1 and the first electrode layer EL1 are sequentially provided on the substrate SUB, and the light emitting layer EL is interposed between the first and second electrode layers EL1 and EL2.

The light emitting layer EL includes the first poly-crystalline silicon layer PSL1, the silicon quantum dot layer SQD, and the second poly-crystalline silicon layer PSL2 sequentially stacked on the first electrode layer EL1. The silicon quantum dot layer SQD includes silicon quantum dots formed in an amorphous silicon layer. The silicon quantum dots are uniformly distributed in the amorphous silicon layer.

According to the display device of the sixth exemplary embodiment, if a predetermined voltage is supplied to the first and second electrode layers EU and EL2, energy is applied to the silicon quantum dot layer SQD. When the energy is applied to the silicon quantum dots, the silicon quantum dots absorb the energy and transit to an excited state. The silicon quantum dots transit to a ground state while emitting a light to the outside. In this case, the wavelength of the emitted light has a value corresponding to the band gap. If the silicon quantum dots are adjusted in size and composition, the light emitting properties such as the wavelength and the intensity of the emitted light can be adjusted due to the quantum confinement effect.

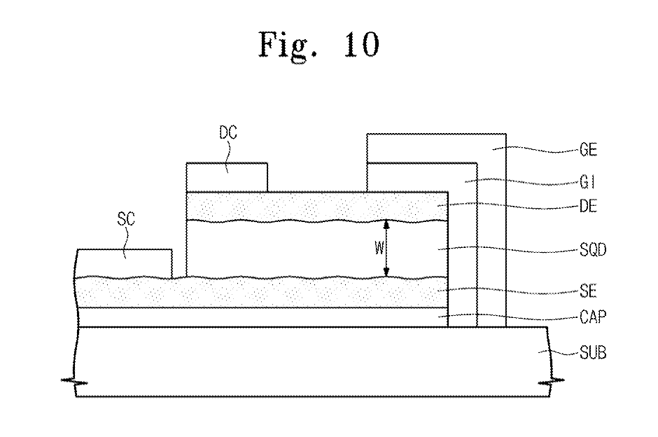

FIG. 10 is a sectional view showing a thin film transistor substrate SUB including the silicon quantum dot layer SQD according to a seventh exemplary embodiment of the present disclosure.

The thin film transistor substrate SUB according to the seventh exemplary embodiment includes the substrate SUB, a capping layer CAP, a source electrode SE, a drain electrode DE, the silicon quantum dot layer SQD, a gate insulating layer GI, and a gate electrode GE.

The capping layer CAP is provided on the substrate SUB.

The source electrode SE is provided on the capping layer CAP, and includes the first poly-crystalline silicon layer PSL1 (not shown).

The silicon quantum dot layer SQD includes silicon quantum dots formed in an amorphous silicon layer. The silicon quantum dots are uniformly distributed in the amorphous silicon layer. The silicon quantum dots may be formed having various sizes to achieve different energy band gap according to the quantum confinement effect. Accordingly, the silicon quantum dots constitute a semiconductor layer by adjusting the energy band gap.

The drain electrode DE is provided on the silicon quantum dot layer SQD, and includes the second poly-crystalline silicon layer PSL2 (not shown).

The first poly-crystalline silicon layer PSL1 is doped with the first conductive type impurities creating an excess of the first type of electron charge carrier, and the second poly-crystalline silicon layer PSL2 is doped with the second conductive type impurities creating an excess of the first type of electron charge carrier having a polarity opposite to a polarity of the first type of electron charge carrier. Accordingly, the first and second poly-crystalline silicon layers PSL1 and PSL2 may have conductivity. According to one exemplary embodiment of the present disclosure, the first poly-crystalline silicon layer PSL1 may include a P type conductive layer formed by doping boron (B) into a poly-crystalline silicon layer and having an excess of holes as compared to electrons, and the second poly-crystalline silicon layer PSL2 may include an N type conductive layer formed by doping phosphorous (P) into a poly-crystalline silicon layer and having an excess of electrons as compared to holes. According to another exemplary embodiment of the present disclosure, the first poly-crystalline silicon layer PSL1 may include the N type conductive layer formed by doping phosphorous (P) into the poly-crystalline silicon layer and having an excess of electrons, and the second poly-crystalline silicon layer PSL2 may include the P type conductive layer formed by doping boron (B) into a poly-crystalline silicon layer and having an excess of holes.

The gate insulating layer GI covers portions of the source electrode SE, the silicon quantum dot layer SQD, and the drain electrode DE. In more detail, the gate insulating layer GI covers a part of exposed portions of the source electrode SE, the drain electrode GE, and the silicon quantum dot layer SQD between the exposed source electrode SE and drain electrode DE.

The gate electrode GE is separated from the source and drain electrodes SE and DE by the gate insulating layer GI. The gate electrode GE overlaps portions of the source electrode SE and the drain electrode DE. In this case, if a voltage is applied to the gate electrode GE, a conductive channel is formed in the silicon quantum dot layer SQD between the source electrode SE and the drain electrode DE.

A source contact part SC is provided on the source electrode SE separated from the silicon quantum dot layer SQD while making physical contact with the source electrode SE. A drain contact part DC is provided on the drain electrode DE spaced apart from the gate insulating layer GI while making physical contact with the drain electrode DE.

According to the seventh exemplary embodiment, the silicon quantum dot layer SQD may have various thicknesses. Accordingly, the width W of the channel can be adjusted by adjusting the thickness of the silicon quantum dot layer SQD. For example, when the silicon quantum dot layer SQD includes a semiconductor layer, the width W of the channel may be in a range of about 0.2 μm to about 3 μm. The width W of the channel in the range is significantly less than that of an amorphous/poly-crystalline silicon thin film transistor. As described above, since the width W of the channel can be significantly reduced, a thin film transistor can be formed in small size.

Although the exemplary embodiments of the present disclosure have been described, it is understood that the present disclosure should not be limited to these exemplary embodiments but various changes and modifications can be made by one ordinary skilled in the art within the spirit and scope of the present disclosure as hereinafter claimed.

What is claimed is:

1. A method comprising:
forming a first capping layer on a substrate;
forming a silicon-containing precursor layer on the first capping layer;
forming a second capping layer on the silicon-containing precursor layer; and
irradiating the first capping layer, the silicon-containing precursor layer, and the second capping layer to convert the silicon-containing precursor layer into a stack comprising a first poly-crystalline silicon layer, a silicon quantum dot layer on the first poly-crystalline silicon layer, and a second poly-crystalline silicon layer on the silicon quantum dot layer.

2. The method of claim 1, wherein the silicon-containing precursor layer comprises at least one of amorphous silicon (a-Si), silicon-rich silicon nitride (SiN), silicon-rich silicon dioxide (SiO), and silicon-rich silicon carbide (SiC).

3. The method of claim 1, wherein the first and second capping layers comprise at least one of silicon oxide (SiO₂), silicon nitride (SiN), and silicon oxynitride (SiON).

4. A method of manufacturing a photovoltaic conversion device, the method comprising:
forming a first capping layer on a substrate;
forming a first electrode layer on the first capping layer;
forming a silicon-containing precursor layer on the first electrode layer, the silicon-containing precursor layer comprising a stack having a first precursor layer doped with first conductive type impurities, a intermediate precursor layer formed on the first precursor layer, and a second precursor layer doped with second conductive type impurities and formed on the intermediate precursor layer;
forming a second capping layer on the second precursor layer;
irradiating the first capping layer, the silicon-containing precursor layer, and the second capping layer to convert the silicon-containing precursor layer into a photovoltaic conversion layer comprising a silicon quantum dot layer;
removing the second capping layer; and
forming a second electrode layer on the photovoltaic conversion layer.

5. The method of claim 4, wherein the photovoltaic conversion layer comprises a stack having a first poly-crystalline silicon layer, the silicon quantum dot layer on the first poly-crystalline silicon layer, and a second poly-crystalline silicon layer on the silicon quantum dot layer.

6. The method of claim 5, further comprising forming a plurality of photovoltaic conversion cells on the substrate,
wherein each photovoltaic conversion cell comprises portions of the first electrode layer, the photovoltaic conversion layer, and the second electrode layer,
wherein the substrate comprises a plurality of cell regions, and
wherein the plurality of photovoltaic conversion cells correspond to the plurality of cell regions in one-to-one correspondence, and wherein the plurality of photovoltaic conversion cells are connected to each other in series.

7. The method of claim 5, further comprising hydrotreating the first poly-crystalline silicon layer, the silicon quantum dot layer, and the second poly-crystalline silicon layer after removing the second capping layer.

8. The method of claim 4, wherein the silicon-containing precursor layer comprises at least one of a-Si, silicon-rich SiN, silicon-rich SiO, and silicon-rich SiC.

9. The method of claim 4, wherein the first and second capping layers comprise at least one of SiO₂, SiN, and SiON.

10. A photovoltaic conversion device comprising:
a substrate;
a capping layer provided on the substrate;
a first electrode layer provided on the capping layer;
a photovoltaic conversion layer provided on the first electrode layer and comprising a silicon quantum dot layer; and
a second electrode layer provided on the photovoltaic conversion layer.

11. The photovoltaic conversion device of claim 10, wherein the photovoltaic conversion layer comprises:
a first poly-crystalline silicon layer provided on the first electrode layer and doped with first conductive type impurities, wherein the silicon quantum dot layer is provided on the first poly-crystalline silicon layer; and
a second poly-crystalline silicon layer provided on the silicon quantum dot layer and doped with second conductive type impurities.

12. The photovoltaic conversion device of claim 11, further comprising a reflective layer interposed between the second poly-crystalline silicon layer and the second electrode layer.

13. The photovoltaic conversion device of claim 12, further comprising:
a first micro-crystalline silicon layer provided on the second poly-crystalline silicon layer and doped with the first conductive type impurities;
an intrinsic micro-crystalline silicon layer provided on the first micro-crystalline silicon layer; and
a second micro-crystalline silicon layer doped with the second conductive type impurities,
wherein the first micro-crystalline silicon layer, the intrinsic micro-crystalline silicon layer and the second micro-crystalline silicon layer are sequentially stacked between the second poly-crystalline silicon layer and the reflective layer.

14. The photovoltaic device of claim 10, wherein the first electrode layer comprises a transparent conductive oxide comprising at least one of zinc oxide (ZnO), tin oxide (SnO₂), indium tin oxide (ITO), indium zinc oxide (IZO), and indium tin zinc oxide (ITZO).

15. The photovoltaic conversion device of claim 10, wherein the substrate comprises a plurality of cell regions,
wherein the first electrode layer, the photovoltaic conversion layer, and the second electrode layer constitute a photovoltaic conversion cell,
wherein a plurality of photovoltaic conversion cells are provided on the substrate and correspond to the cell regions in one-to-one correspondence, and
wherein the plurality of photovoltaic conversion cells are connected to each other in series.

16. A display device comprising a plurality of pixels, wherein each pixel comprises:
a capping layer provided on a substrate;
a first electrode layer provided on the capping layer;
a light emitting layer provided on the first electrode layer and comprising a silicon quantum dot layer; and
a second electrode layer provided on the light emitting layer.

17. The display device of claim 16, wherein the light emitting layer comprises:
a first poly-crystalline silicon layer provided on the first electrode layer and doped with first conductive type impurities, wherein the silicon quantum dot layer is provided on the first poly-crystalline silicon layer; and
a second poly-crystalline silicon layer provided on the silicon quantum dot layer and doped with second conductive type impurities.

18. The display device of claim 17, further comprising a reflective layer interposed between the second poly-crystalline silicon layer and the second electrode layer.

19. The display device of claim 17, wherein the first electrode layer comprises a transparent conductive oxide comprising at least one of ZnO, SnO₂, ITO, IZO, or ITZO.

20. A thin film transistor substrate comprising:
a capping layer provided on a substrate;
a source electrode comprising a poly-crystalline silicon layer provided on the capping layer and doped with first conductive type impurities;
a drain electrode comprising a poly-crystalline silicon layer doped with second conductive type impurities;
a silicon quantum dot layer forming a channel interposed between the source electrode and the drain electrode;
a gate insulating layer covering the channel; and
a gate electrode provided on the gate insulating layer.

21. The thin film transistor substrate of claim 20, further comprising:
a source contact provided on the source electrode and separated from the silicon quantum dot layer; and
a drain contact provided on the drain electrode and spaced apart from the gate insulating layer.
